(19) United States
(12) Patent Application Publication
(10) Pub. No.: US 2024/0343969 A1
(43) Pub. Date: Oct. 17, 2024

(54) METHOD FOR RECYCLING AN LED

(71) Applicants: PARIS SCIENCES ET LETTRES, Paris (FR); CENTRE NATIONAL DE LA RECHERCHE SCIENTIFIQUE, Paris (FR); ECOLE NATIONALE SUPERIEURE DE CHIMIE DE PARIS, Paris (FR)

(72) Inventors: Moheddine WEHBIE, PARIS (FR); Vincent SEMETEY, LE MANS (FR); Michel MINIER, ANTONY (FR)

(73) Assignees: PARIS SCIENCES ET LETTRES, Paris (FR); CENTRE NATIONAL DE LA RECHERCHE SCIENTIFIQUE, Paris (FR); ECOLE NATIONALE SUPERIEURE DE CHIMIE DE PARIS, Paris (FR)

(21) Appl. No.: 18/293,552

(22) PCT Filed: Jul. 29, 2022
(86) PCT No.: PCT/FR2022/051525

§ 371 Date: Jan. 30, 2024

(30) Foreign Application Priority Data
Jul. 30, 2021 (FR) 2108299

(51) Int. Cl. C09K 11/01; C09K 11/77; C22B 3/44; C22B 7/00; C22B 11/00; C22B 15/00; H01L 33/00

(52) U.S. Cl. CPC C09K 11/01; C09K 11/7701; C09K 11/7706; C09K 11/7774; C22B 3/44; C22B 7/007; C22B 11/046; C22B 15/0073; C22B 15/0089; H01L 33/005; H01L 2933/005

(57) ABSTRACT

A method for extracting and separating at least one component from a LED, the LED including at least one metal, at least one phosphor and at least one layer including polydimethylsiloxane. Also, an LED having at least one layer including polydimethylsiloxane, wherein the at least one layer comprising polydimethylsiloxane is depolymerized by the action of a solution including a solvent and a fluorine salt.

### FIELD OF THE INVENTION

The present invention relates to a method for recycling LEDs comprising at least one metal, at least one phosphor and at least one layer comprising polydimethylsiloxane. This method comprises a step of depolymerization of the at least one layer comprising polydimethylsiloxane of the LED, the extraction of the at least one phosphor, then a step of recovery of the at least one metal of the LED.

### STATE OF THE ART

LEDs constitute a technological breakthrough in the field of lamps given their advantages of consuming less energy, lasting longer and allowing various shades of light to be obtained (notably warm light and cold light). Since they now represent the majority of sales in the field of lamps, recycling them has become a major challenge.

Usually, the different elements of an LED are as follows: phosphor, semiconductor, connectors, housing, electrodes, generally covered at least partially with a lens consisting of at least one layer comprising polydimethylsiloxane. A phosphor is usually composed of a Yttrium aluminum garnet (YAG) type material doped with rare earths. A semiconductor usually comprises gallium and indium. An electrode usually comprises silver, copper and iron. A connector usually comprises gold.

LED components are not currently recycled. Nevertheless, certain recycling processes including pyrometallurgical processes or processes involving the use of strong acids are being studied.

However, these methods do not allow the recovery of all the elements of the LED. In particular, the phosphor cannot be recycled via these methods. However, the phosphor comprises critical metals which have a very high intrinsic value; additionally, reduced consumption of raw materials and geopolitical factors make the recycling of these critical metals even more important.

In addition, in the case of processes using strong acids, all the elements of the LED are mixed together and cannot be recycled separately and simply.

The present invention aims to solve the problem of providing a LED recycling method making it possible to successively recover the different elements present in the LEDs, in particular the phosphor and at least one metal.

### SUMMARY

The present invention relates to a method for extracting and separating at least one component of an LED, the LED comprising at least one metal, at least one phosphor and at least one layer comprising polydimethylsiloxane, said method comprising the following steps:
a) at least partial depolymerization of at least one layer comprising polydimethylsiloxane using a solution comprising a solvent and a fluoride salt;
b) separation of the at least one phosphor and the rest of the LED obtained in step a);
c) contacting at least one acidic solution with the rest of the LED obtained in step b); and
d) separation of the at least one acidic solution comprising at least part of the at least one metal and the rest of the LED obtained in step c).

In one embodiment, the solvent of the solution used in step a) is selected from the group consisting of tetrahydrofuran, methyltetrahydrofuran, dichloromethane, trichloromethane, acetonitrile, dimethylformamide, N-methyl-2-pyrrolidone, binary solvents, and mixtures thereof, the binary solvents being selected from the group consisting of methyltetrahydrofuran and acetone, methyltetrahydrofuran and acetonitrile, methyltetrahydrofuran and dimethylformamide, and methyltetrahydrofuran and trichloromethane, preferably the solvent of the solution used in step a) is a mixture of methyltetrahydrofuran and acetone or methyltetrahydrofuran and acetonitrile.

In one embodiment, the fluoride salt of the solution used in step a) is a quaternary ammonium fluoride selected from the group consisting of tetrabutylammonium fluoride (TBAF), tetramethylammonium fluoride (TMAF), tetraethylammonium fluoride (TEAF) and tetra-n-octylammonium fluoride (TOAF), preferably the fluoride salt of the solution used in step a) is tetrabutylammonium fluoride.

In one embodiment, the at least one acidic solution used in step c) is selected from the group consisting of nitric acid, sulfuric acid, aqua regia, an acidic thiourea solution, a mixture of NaClO—HCl—H₂O₂, a mixture of (acetic acid-HCl—CaCl₂—H₂O₂), a mixture HCl—H₂O₂ and mixtures thereof, preferably the at least one acidic solution used in step c) is nitric acid.

In one embodiment, the at least one acidic solution used in step c) is selected from the group consisting of nitric acid, sulfuric acid, aqua regia, an acidic thiourea solution, a mixture of NaClO—HCl—H₂O₂ and mixtures thereof, preferably the at least one acidic solution used in step c) is nitric acid.

In one embodiment, the method further comprises recovering at least a part of the at least one metal by a step e) of separating the at least one acidic solution from at least a part of the at least one metal, for example by precipitation and/or filtration.

In one embodiment, the sequence of method steps c) and d) is repeated with at least one solution different from that used in the first sequence of steps c) and d).

In one embodiment, the at least one metal of the LED is selected from the group consisting of gold, silver, copper, aluminum, tin, iron and combinations thereof.

In one embodiment, the at least one LED is coated by a polyester layer or is present in a polyester layer, and wherein said method comprises, prior to step a), a step 0) of degrading at least a part of the polyester layer using a solution comprising a solvent and a fluorine salt, preferably the solution comprising a solvent and a fluorine salt used in step 0) is identical to that used in step a).

In one embodiment, steps 0) and a) are successive or concomitant.

The present invention also relates to an LED comprising at least one layer comprising polydimethylsiloxane, wherein the at least one layer comprising polydimethylsiloxane is depolymerized by the action of a solution comprising a solvent and a fluorine salt, preferably said solution comprises tetrabutylammonium fluoride in a solvent mixture comprising methyltetrahydrofuran and acetone or methyltetrahydrofuran and acetonitrile.

### DEFINITIONS

In the present invention, the terms below are defined as follows:

“Aqua regia” refers to a mixture of hydrochloric acid and nitric acid with an HCl:HNO₃ volume ratio of 3:1 or 4:1. According to one embodiment, “aqua regia” refers to a mixture of hydrochloric acid and nitric acid with an HCl:HNO₃ volume ratio of 3:1. According to a preferred embodiment, “aqua regia” refers to a mixture of hydrochloric acid and nitric acid with an HCl:HNO₃ volume ratio of 4:1.

“Comprising” or “comprise” is to be interpreted in an open and inclusive sense, but not limited to. In one embodiment, “comprising” means “consisting essentially of”. In one embodiment, “comprising” means “consisting of”, which is to be interpreted as limited to.

“From X to Y” refers to the range of values between X and Y, the limits X and Y being included in said range.

“LED” or “DEL” refers to a light-emitting diode, i.e. an optoelectronic device capable of emitting light when an electric current flows through it. “LED” or “DEL” also includes organic derivatives of LEDs, such as, for example, an organic light-emitting diode (OLED), in particular in an active-or passive-matrix organic light-emitting diode (Active-Matrix Organic Light-emitting Diode AMOLED or Passive-Matrix Organic Light-emitting Diode PMOLED), or a flexible organic light-emitting diode (FOLED).

“About”, before a figure or number, means plus or minus 10% of the nominal value of that figure or number. In one embodiment, “about”, before a figure or number, refers to plus or minus 5% of the nominal value of that figure or number.

“Depolymerizing” refers to the breaking of at least one covalent bond between 2 units within a polymer. According to one embodiment, “depolymerizing” refers to the breaking of at least one covalent bond between 2 dimethylsiloxane units. “Depolymerizing” includes both total polymer depolymerization and partial polymer depolymerization, also called fragmentation.

“Phosphor” refers to a substance which, when excited, emits light. In particular, the phosphor may be selected from the group consisting of garnets of the type Y₃Al₅O₁₂ (YAG), Gd₃Sc₂Al₃O₁₂, (Gd,Y)₃Al₅O₁₂, Lu₃Al₅O₁₂ and Y₃Al₂Ga₃O₁₂, doped with at least one rare earth, in particular europium Eu, cerium Ce, ytterbium Yb, gadolinium Gd, lutetium Lu, yttrium Y or neodymium Nd, or with at least one metal such as a critical metal. According to one embodiment, the phosphor is a yttrium aluminum garnet (YAG) material of chemical formula Y₃Al₂(AlO₄)₃ doped with at least one rare earth such as europium Eu, cerium Ce, ytterbium Yb, gadolinium Gd, lutetium Lu, yttrium Y or neodymium Nd, and/or at least one critical metal such as gallium Ga or indium In. In an LED, the phosphor transforms the blue light produced by the semiconductor into daylight.

“Metal” refers to any type of metal including alkali metals, alkaline earth metals, lanthanides, actinides, transition metals and poor metals. According to one embodiment, “metal” comprises or consists of gold, silver, copper, iron, tin, aluminum, bismuth, gallium, nickel, lead and indium. According to one embodiment, “metal” comprises or consists of gold, silver, copper, iron, tin, aluminum, bismuth, gallium and indium. According to one embodiment, “metal” comprises or consists of gold, silver, copper, iron, tin and aluminum. “Metal” includes precious and non-precious metals. According to the present invention, “precious metals” refers to gold and silver. According to the present invention, “non-precious metals” refers to any metal not included in the above list of precious metals, for example copper, iron, tin, aluminum, nickel, lead, bismuth, gallium and indium. According to one embodiment, “non-precious metals” comprises or consists of copper, iron, tin and aluminum.

“Critical metal” refers to any metal which may have a significant negative industrial or economic impact due to a difficult, unpredictable supply. In other words, “critical metal” refers to any metal with economic importance and/or high supply risk. Examples of critical metals include rare earths (notably europium Eu, cerium Ce, ytterbium Yb, gadolinium Gd, lutetium Lu, yttrium Y, neodymium Nd), as well as gallium Ga and indium In.

“Fluorine salt” refers to a salt comprising at least one fluoride ion and at least one organic or inorganic cation.

### DETAILED DESCRIPTION

### Method for Separating at Least One LED Component

### LED

The present invention relates to a method for extracting and separating at least one component from an LED.

The LED according to the invention comprises at least one metal, at least one phosphor and at least one layer comprising polydimethylsiloxane (PDMS). Preferably, the LED comprises at least one precious metal, at least one phosphor and at least one layer comprising polydimethylsiloxane.

In one embodiment, the LED comprises, from outside to inside: at least one layer comprising polydimethylsiloxane, at least one phosphor and at least one metal, preferably at least one precious metal. In other words, the at least one phosphor and the at least one metal, preferably the at least one precious metal, are in the volume delimited at least in part by the at least one layer comprising polydimethylsiloxane.

According to one embodiment, the at least one metal of the LED is selected from the group consisting of gold, silver, copper, iron, tin, aluminum, bismuth, gallium, nickel, lead and indium. Preferably, the at least one metal of the LED is selected from the group consisting of gold, silver, copper, iron, tin, aluminum, bismuth, gallium, indium, nickel and combinations thereof. More preferably, the at least one metal of the LED is selected from the group consisting of gold, silver, copper, iron, tin, aluminum, bismuth, gallium, indium and combinations thereof. Even more preferably, the at least one metal of the LED is selected from the group consisting of gold, silver, copper, iron, tin, aluminum and combinations thereof.

According to one embodiment, the at least one metal of the LED is a non-precious metal. Preferably, said non-precious metal is selected from the group consisting of copper, iron, tin, aluminum, bismuth, gallium, indium, lead, nickel and combinations thereof. More preferably, said non-precious metal is selected from the group consisting of copper, iron, tin, aluminum, bismuth, gallium, indium, nickel and combinations thereof. Even more preferably, said non-precious metal is selected from the group consisting of copper, iron, tin, aluminum, bismuth, gallium, indium and combinations thereof. Advantageously, said non-precious metal is selected from the group consisting of copper, iron, tin, aluminum and combinations thereof.

According to one embodiment, the at least one metal of the LED is a precious metal. Preferably, said precious metal is selected from the group consisting of gold, silver and combinations thereof.

### Process Steps

The method comprises the steps of recovering the at least one phosphor by depolymerizing the polydimethylsiloxane, and then recovering the at least one metal. Recovering the at least one metal may be achieved by leaching metal fraction(s). Then, the at least one leached metal fraction may be recovered by a hydrometallurgical process, precipitation and/or electrodeposition.

According to one embodiment, the method comprises the following steps:
a) At least partial depolymerization of the at least one layer comprising polydimethylsiloxane using a solution comprising at least one solvent and at least one fluorine salt;
b) Separation of the at least one phosphor from the rest of the LED obtained in step a);
c) Contacting at least one solution, preferably an acidic solution, with the LED rest obtained in step b); and
d) Separation of the at least one solution, preferably the at least one acidic solution, comprising at least part of the at least one metal and of the rest of the LED obtained in step c).

In one embodiment, steps a), b), c) and d) are carried out in the order step a) then step b) then step c) then step d).

In another embodiment, steps a), b), c) and d) are carried out in an order different from the order step a) then step b) then step c) then step d). For example, steps a), b), c) and d) may be carried out in the following order: step a) then step b) then step a) then step c) then step d).

In one embodiment, steps a), b), c) and d) are carried out in the following order: step a) then step b) then step c) then step d) then step c) then step d).

In one embodiment, the sequences of two or three steps are repeated at least twice.

### Step a)

Step a) of the method according to the invention is the step of at least partial depolymerization of the at least one layer comprising polydimethylsiloxane using a solution comprising a solvent and a fluorine salt. This step makes it possible to access the components of the LED which are at least partially covered by the at least one layer comprising polydimethylsiloxane

When it is partial, the depolymerization carried out in step a) must be sufficient to make it possible to extract the phosphor and thus implement step b). In one embodiment, at least 10% of the polymer, preferably at least 20%, in particular at least 50%, even more preferably at least 80% of the polymer is depolymerized

According to one embodiment, the fluorine salt of the solution used in step a) is a quaternary ammonium fluoride selected from the group consisting of tetrabutylammonium fluoride (TBAF), tetramethylammonium fluoride (TMAF), tetraethylammonium fluoride (TEAF) and tetra-n-octylammonium fluoride (TOAF). Preferably, the fluorine salt of the solution used in step a) is tetrabutylammonium fluoride (TBAF).

According to one embodiment, the solution comprising a solvent and a fluorine salt used in step a) comprises at least 0.005 mmol of TBAF per 1 mmol of dimethylsiloxane residues (monomers) in the PDMS to be depolymerized. Preferably, the solution comprising a solvent and a fluorine salt used in step a) comprises at least 0.01 mmol of TBAF per 1 mmol of dimethylsiloxane residues in PDMS to be depolymerized. More preferably, the solution comprising a solvent and a fluorine salt used in step a) comprises at least 0.04 mmol of TBAF per 1 mmol of dimethylsiloxane residues in PDMS to be depolymerized. More preferably, the solution comprising a solvent and a fluorine salt used in step a) comprises at least 0.1 mmol of TBAF per 1 mmol of dimethylsiloxane residues in PDMS to be depolymerized. More preferably, the solution comprising a solvent and a fluorine salt used in step a) comprises at least 0.2 mmol of TBAF per 1 mmol of dimethylsiloxane residues in PDMS to be depolymerized. More preferably the solution comprising a solvent and a fluorine salt used in step a) comprises at least 1 mmol of TBAF per 1 mmol of dimethylsiloxane residues in PDMS to be depolymerized.

According to one embodiment, the solution comprising a solvent and a fluorine salt used in step a) comprises at most 100 mmol of TBAF per 1 mmol of dimethylsiloxane residues in the PDMS to be depolymerized. According to one embodiment, the solution comprising a solvent and a fluorine salt used in step a) comprises at most 10 mmol of TBAF per 1 mmol of dimethylsiloxane residues in the PDMS to be depolymerized. Preferably, the solution comprising a solvent and a fluorine salt used in step a) comprises at most 5 mmol of TBAF per 1 mmol of dimethylsiloxane residues in the PDMS to be depolymerized. More preferably, the solution comprising a solvent and a fluorine salt used in step a) comprises at most 4 mmol of TBAF per 1 mmol of dimethylsiloxane residues in PDMS to be depolymerized. More preferably, the solution comprising a solvent and a fluorine salt used in step a) comprises at most 3 mmol of TBAF per 1 mmol of residues dimethylsiloxane in PDMS to be depolymerized. More preferably, the solution comprising a solvent and a fluorine salt used in step a) comprises at most 2 mmol of TBAF per 1 mmol of dimethylsiloxane residues in PDMS to be depolymerized. More preferably, the solution comprising a solvent and a fluorine salt used in step a) comprises at most 1 mmol of TBAF per 1 mmol of dimethylsiloxane residues in PDMS to be depolymerized.

According to one embodiment, the solution comprising a solvent and a fluorine salt used in step a) comprises from 0.005 mmol to 10 mmol of TBAF per 1 mmol of dimethylsiloxane residues in PDMS to be depolymerized. Preferably, the solution comprising a solvent and a fluorine salt used in step a) comprises from 0.01 mmol to 5 mmol of TBAF per 1 mmol of dimethylsiloxane residues in PDMS to be depolymerized. More preferably, the solution comprising a solvent and a fluorine salt used in step a) comprises from 0.04 mmol to 4 mmol of TBAF per 1 mmol of dimethylsiloxane residues in PDMS to be depolymerized. More preferably, the solution comprising a solvent and a fluorine salt used in step a) comprises from 0.1 mmol to 3 mmol of TBAF per 1 mmol of dimethylsiloxane residues in PDMS to be depolymerized. More preferably, the solution comprising a solvent and a fluorine salt used in step a) comprises from 0.2 mmol to 2 mmol of TBAF per 1 mmol of dimethylsiloxane residues in PDMS to be depolymerized. More preferably, the solution comprising a solvent and a fluorine salt used in step a) comprises from 1 mmol to 2 mmol of TBAF per 1 mmol of dimethylsiloxane residues in PDMS to be depolymerized.

A skilled artisan is able to adapt the various conditions of implementation of step a), in particular the temperature and/or the duration of step a) depending in particular on the amount of PDMS to be depolymerized, the nature and/or concentration of the solvent and the fluorine salt. According to one embodiment, step a) lasts less than 5 days, preferably less than 48 hours, even more preferably less than 30 hours. Preferably, step a) lasts less than 24 h. More preferably, step a) lasts less than 4 hours. More preferably, step a) lasts less than 3 hours. More preferably, step a) lasts less than 2 hours. More preferably, step a) lasts less than 1 hour. More preferably, step a) lasts less than 30 minutes. Even more preferably, step a) lasts less than 20 minutes.

According to one embodiment, the solution comprising a solvent and a fluorine salt used in step a) comprises at least 0.005 mmol of TBAF per 1 mmol of dimethylsiloxane residues in PDMS to be depolymerized and step a) lasts less than 5 days.

According to one embodiment, the solution comprising a solvent and a fluorine salt used in step a) comprises at least 0.01 mmol of TBAF per 1 mmol of dimethylsiloxane residues in PDMS to be depolymerized and step a) lasts less than 48 hours.

According to one embodiment, the solution comprising a solvent and a fluorine salt used in step a) comprises at least 0.04 mmol of TBAF per 1 mmol of dimethylsiloxane residues in PDMS to be depolymerized and step a) lasts less than 3 hours.

According to one embodiment, the solution comprising a solvent and a fluorine salt used in step a) comprises at least 0.05 mmol of TBAF per 1 mmol of dimethylsiloxane residues in PDMS to be depolymerized and step a) lasts less than 2 hours.

According to one embodiment, the solution comprising a solvent and a fluorine salt used in step a) comprises at least 0.1 mmol of TBAF per 1 mmol of dimethylsiloxane residues in PDMS to be depolymerized and step a) lasts less than 1 hour.

According to one embodiment, the solution comprising a solvent and a fluorine salt used in step a) comprises at least 0.2 mmol of TBAF per 1 mmol of dimethylsiloxane residues in PDMS to be depolymerized and step a) lasts less than 30 minutes.

According to one embodiment, the solution comprising a solvent and a fluorine salt used in step a) comprises at least 0.4 mmol of TBAF per 1 mmol of dimethylsiloxane residues in PDMS to be depolymerized and step a) lasts less than 20 minutes.

In one embodiment, the solvent of the solution used in step a) is selected from the group consisting of tetrahydrofuran (THF), methyltetrahydrofuran (Me—THF or CH₃—THF), dichloromethane (DCM), trichloromethane, acetonitrile, dimethylformamide (DMF) and N-methyl-2-pyrrolidone (NMP).

In one embodiment, the solution used in step a) further comprises a second solvent. The second solvent is preferably selected from the group consisting of acetone, acetonitrile, dimethylformamide, cyclohexane, tetrahydrofuran, dichloromethane and trichloromethane.

In one embodiment, the solution used in step a) comprises a binary solvent, that is to say a mixture of exactly two solvents, one of the solvents being chosen from the group 1 consisting of tetrahydrofuran (THF), methyltetrahydrofuran (Me—THF), dichloromethane (DCM), trichloromethane, acetonitrile, dimethylformamide (DMF) and N-methyl-2-pyrrolidone (NMP), and the other solvent being selected from group 2 consisting of acetone, acetonitrile, dimethylformamide, cyclohexane and trichloromethane.

In one embodiment, the binary solvent comprises about 50% solvent from group 1 and about 50% solvent from group 2. In one embodiment, the binary solvent comprises about 60% solvent from group 1 and about 40% solvent from group 2. In one embodiment, the binary solvent comprises about 70% solvent from group 1 and about 30% solvent from group 2. In one embodiment, the binary solvent comprises about 80% solvent from group 1 and about 20% solvent from group 2. In one embodiment, the binary solvent comprises about 90% solvent from group 1 and about 10% solvent from group 2. In one embodiment, the binary solvent comprises about 95% solvent from group 1 and about 5% solvent from group 2. In one embodiment, the binary solvent comprises about 96% solvent from group 1 and about 4% solvent from group 2. In one embodiment, the binary solvent comprises about 97% solvent from group 1 and about 3% solvent from group 2. In one embodiment, the binary solvent comprises about 98% solvent from group 1 and about 2% solvent from group 2. In one embodiment, the binary solvent comprises about 99% solvent from group 1 and about 1% solvent from group 2. In one embodiment, the binary solvent comprises about 99.5% solvent from group 1 and about 0.5% solvent from group 2. The percentages are expressed by volume relative to the volume of binary solvent.

In one embodiment, the solution used in step a) comprises a ternary solvent, that is to say exactly a mixture of exactly 3 solvents, one of the solvents being chosen from the group 1 consisting of tetrahydrofuran (THF), methyltetrahydrofuran (Me—THF), dichloromethane (DCM), trichloromethane, acetonitrile, dimethylformamide (DMF) and N-methyl-2-pyrrolidone (NMP), and the other two solvents being selected from group 2 consisting of acetone, acetonitrile, dimethylformamide, cyclohexane and trichloromethane.

In one embodiment, the ternary solvent comprises about 50% solvent from group 1 and about 50% solvent from group 2. In one embodiment, the binary solvent comprises about 60% solvent from group 1 and about 40% solvents from group 2. In one embodiment, the binary solvent comprises about 70% solvent from group 1 and about 30% solvent from group 2. In one embodiment, the binary solvent comprises about 80% solvent from group 1 and about 20% solvents from group 2. In one embodiment, the binary solvent comprises about 90% solvent from group 1 and about 10% solvents from group 2. In one embodiment, the binary solvent comprises about 95% solvent from group 1 and about 5% solvents from group 2. In one embodiment, the binary solvent comprises about 96% solvent from group 1 and about 4% solvents from group 2. In one embodiment, the binary solvent comprises about 97% solvent from group 1 and about 3% solvents from group 2. In one embodiment, the binary solvent comprises about 98% solvent from Group 1 and about 2% solvents from group 2. In one embodiment, the binary solvent comprises about 99% solvent from group 1 and about 1% solvents from group 2. In one embodiment, the binary solvent comprises about 99.5% of solvent from group 1 and about 0.5% of solvents from group 2. The percentages are expressed by volume relative to the volume of ternary solvent.

In particular, the binary solvents can be chosen from the group consisting of:
methyltetrahydrofuran and acetone,
methyltetrahydrofuran and acetonitrile,
methyltetrahydrofuran and dimethylformamide,
methyltetrahydrofuran and dichloromethane.

Advantageously, the solvent of the solution used in step a) is a mixture:
methyltetrahydrofuran and acetone, or
methyltetrahydrofuran and acetonitrile, or
methyltetrahydrofuran, acetone and acetonitrile.

Advantageously, the solvent of the solution used in step a) is a mixture of:
methyltetrahydrofuran and acetone, or
methyltetrahydrofuran and acetonitrile.

According to one embodiment, the solution comprising a solvent and a fluorine salt used in step a) comprises TBAF and a solvent selected from the group consisting of tetrahydrofuran, dichloromethane, trichloromethane, acetonitrile, dimethylformamide, N-methyl-2-pyrrolidone and methyltetrahydrofuran.

According to one embodiment, the solution comprising a solvent and a fluorine salt used in step a) comprises TBAF and a solvent selected from the group consisting of tetrahydrofuran, dichloromethane, trichloromethane, acetonitrile and methyltetrahydrofuran.

According to one embodiment, the solution comprising a solvent and a fluorine salt used in step a) is a solution comprising TBAF and methyltetrahydrofuran. Advantageously, said solution further comprises acetone or acetonitrile. More advantageously, said solution further comprises a few drops of acetone or acetonitrile. According to a preferred embodiment, the solution comprising a solvent and a fluorine salt used in step a) is a solution comprising tetrabutylammonium fluoride in a mixture of solvents comprising methyltetrahydrofuran and acetone or methyltetrahydrofuran and acetonitrile.

Advantageously, the solution comprising a solvent and a fluorine salt used in step a) comprises from 0.01 mmol to 5 mol of TBAF per liter of solvent, in particular per liter of methyltetrahydrofuran. Preferably, the solution comprising a solvent and a fluorine salt used in step a) comprises from 0.04 mmol to 1 mol of TBAF per liter of solvent, in particular per liter of methyltetrahydrofuran. More preferably, the solution comprising a solvent and a fluorine salt used in step a) comprises from 0.2 mmol to 1 mol of TBAF per liter of solvent, in particular per liter of methyltetrahydrofuran. More preferably, the solution comprising a solvent and a fluorine salt used in step a) comprises from 0.1 mmol to 1 mol of TBAF per liter of solvent, in particular per liter of methyltetrahydrofuran. Even more preferably, the solution comprising a solvent and a fluorine salt used in step a) comprises from 0.4 mmol to 1 mol of TBAF per liter of solvent, in particular per liter of methyltetrahydrofuran.

When the solution comprising a solvent and a fluorine salt used in step a) comprises at least 0.4 mmol of TBAF per liter of solvent, in particular methyltetrahydrofuran, step a) advantageously lasts less than 20 minutes.

When the depolymerization of at least one layer comprising polydimethylsiloxane is at least partial, it allows the implementation of step b) of separation of the at least one phosphor and of the rest of the LED obtained in step a).

### Step b)

Step b) of the method according to the invention is the step of separating the at least one phosphor and the rest of the LED obtained in step a). This step makes it possible to recover the at least one phosphor, in particular in order to recycling it.

According to one embodiment, the separation of the at least one phosphor and the rest of the LED obtained in step a) makes it possible to recycle this at least one phosphor. The recycling of the at least one phosphor may consist in its reuse or in the recovery of at least part of some of its compounds, in particular garnet such as YAG and/or all or part of the rare earths and/or critical metals. According to one embodiment, the recycling of the at least one phosphor comprises the recovery of at least one portion of at least one lanthanide. According to one embodiment, the recycling of the at least one phosphor comprises the recovery of at least one portion of at least one critical metal.

According to one embodiment, step b) of separating the at least one phosphor and the rest of the LED obtained in step a) is a mechanical step. Said separation can be carried out manually or automatically, for example using a robot.

According to one embodiment, step b) of separation of the at least one phosphor and of the rest of the LED obtained in step a) is carried out by sedimentation and/or by filtration, in particular by sieve filtration.

This step of separating the at least one phosphor and the rest of the LED obtained in step a) is a highly advantageous step of the method according to the invention. Indeed, thanks to step a) of at least partial depolymerization of the at least one layer comprising polydimethylsiloxane, the intact phosphor can be extracted from the LED during step b). However, this is not possible in the processes of the prior art requiring a grinding step; indeed, a grinding step leads to a loss of the elements which are in a mixture and does not allow a separation of the intact phosphor from the remainder of the LED.

Advantageously, an optional step, intermediate between steps b) and c), of at least one washing and/or drying of the rest of the LED obtained in step b) can be carried out. Preferably, the washing is carried out with acetone as washing solvent.

### Step c

Step c) of the method according to the invention is the step of bringing at least one solution, in particular at least one acidic solution, into contact with the rest of the LED obtained in step b). This step aims to leach at least part of the metals present in the rest of the LED obtained in step b).

According to one embodiment, the at least one solution used in step c) is selected from the group consisting of nitric acid, sulfuric acid, aqua regia, an acid thiourea solution, a cyanide solution, a solution comprising Fe³⁺ thiocyanate, a solution comprising thiosulfate and Cu(NH₃)₄²⁺, a mixture of NaOCl—HCl, a mixture of NaClO—HCl—H₂O₂, a mixture of (acetic acid-HCl—CaCl₂—H₂O₂), a mixture HCl—H₂O₂ and any one of their mixtures. Advantageously, the at least one solution used in step c) is selected from the group consisting of nitric acid, sulfuric acid, aqua regia, an acidic thiourea solution, a cyanide solution, a solution comprising Fe³⁺ thiocyanate, a solution comprising thiosulfate and Cu(NH₃)₄²⁺, a mixture of NaOCl—HCl, a mixture of NaClO—HCl—H₂O₂, and any of their mixtures.

According to one embodiment, the solution used in step c) is an acidic solution. The acidic solution is preferably chosen from nitric acid, sulfuric acid, aqua regia, an acidic thiourea solution, a mixture of NaOCl—HCl, a mixture of NaClO—HCl—H₂O₂, a mixture of (acetic acid-HCl—CaCl₂—H₂O₂), a mixture HCl—H₂O₂ and any of their mixtures. The acidic solution is more preferably chosen from nitric acid, sulfuric acid, aqua regia, an acidic thiourea solution, a mixture of NaOCl—HCl, a mixture of NaClO—HCl—H₂O₂, and any one of their mixtures.

According to one embodiment, the at least one acidic solution used in step c) is selected from the group consisting of nitric acid, aqua regia, an acidic thiourea solution and mixtures thereof.

Advantageously, step c) allows the leaching of at least part of at least one metal from the rest of the LED obtained in step b). More advantageously, the at least one acidic solution used in step c) is chosen as a function of the metal of which at least one portion is to be leached during step c).

The extraction and separation method according to the invention may comprise several successive steps c). Advantageously, a separation step d) is implemented between two successive steps c). In such a method comprising several successive steps c), at least one of steps c) is implemented with an acidic solution.

Preferably, the first step c) of the method according to the invention is implemented with an acidic solution.

According to one embodiment, the method according to the invention comprises a first step c) implemented with an acidic solution, preferably an acidic solution selected from the group consisting of nitric acid, sulphuric acid and any of their mixtures, then a second step c) carried out with a solution, preferably a solution chosen from the group consisting of aqua regia, an acidic thiourea solution, a cyanide solution, a solution comprising Fe³⁺ thiocyanate, a solution comprising thiosulfate and Cu(NH₃)₄²⁺, a mixture of NaOCl—HCl, a mixture of NaClO—HCl—H₂O₂, a mixture of (acetic acid-HCl—CaCl₂—H₂O₂), a mixture HCl—H₂O₂ and any one of their mixtures, more preferably a solution selected from the group consisting of aqua regia, an acidic thiourea solution, a cyanide solution, a solution comprising Fe³⁺ thiocyanate, a solution comprising thiosulfate and Cu(NH₃)₄²⁺, a mixture of NaOCl—HCl, a mixture of NaClO—HCl—H₂O₂, and any of their mixtures.

According to one embodiment, the at least one acidic solution used in step c) is nitric acid, preferably 4 M nitric acid. The nitric acid has the advantage of leaching various metals present in the LED, while leaving intact the gold and the semiconductors of the LED. Thus, the at least one acidic solution used in step c) is advantageously nitric acid in order to allow the leaching of silver, copper, tin and/or iron.

According to one embodiment, the at least one acidic solution used in step c) is sulfuric acid. The sulfuric acid advantageously makes it possible to leach the iron present in the rest of the LED Thus, the at least one acidic solution used in step c) is advantageously sulfuric acid in order to allow the leaching of the iron.

According to one embodiment, the at least one acidic solution used in step c) is from aqua regia, preferably from aqua regia whose volume ratio HCl:HNO₃ is 4:1. The aqua regia advantageously makes it possible to leach the gold present in the rest of the LED Thus, the at least one acidic solution used in step c) is advantageously from aqua regia in order to allow leaching of the gold.

According to one embodiment, the at least one solution used in step c) is selected from the group consisting of aqua regia, an acidic thiourea solution, a cyanide solution, a solution comprising Fe³⁺ thiocyanate, a solution comprising thiosulfate and Cu(NH₃)₄²⁺, a mixture of NaOCl—HCl, a mixture of NaClO—HCl—H₂O₂, and any one of their mixtures, preferably an acidic thiourea solution or a mixture of NaClO—HCl—H₂O₂. This solution advantageously makes it possible to leach the gold present in the rest of the LED. Thus, the at least one acidic solution used in step c) is advantageously an acidic thiourea solution or a mixture of NaClO—HCl—H₂O₂ in order to allow the gold leaching.

The acidic thiourea solution used in step c) may in particular be prepared and/or used as described in Ippolito et al. Materials 2021, 14, 362. The cyanide solution may in particular be prepared and/or used as described in Vorster et al. The Journal of The South African Institute of Mining and Metallurgy 2001, 359. The solution comprising Fe³⁺ thiocyanate may in particular be prepared and/or used as described in Azizitorghabeh et al. ACS Omega 2021, 6, 17183-17193. The solution comprising thiosulfate and Cu(NH₃)₄²⁺ may in particular be prepared and/or implemented as described in Xiang et al. IOP Conf. Series: Materials Science and Engineering 2018, 394, 022001. The mixtures comprising sodium hypochlorite NaOCl can be used under suitable conditions, which are well-known to those skilled in the art.

Step c) may be carried out at any suitable temperature, in particular at ambient temperature or at a higher temperature, in particular at reflux of the acidic solution.

According to one embodiment, a first step c) is carried out with nitric acid, followed by a step d), then a second step c) is carried out with aqua regia, an acidic thiourea solution, a mixture of (acetic acid-HCl—CaCl₂—H₂O₂) or a mixture of NaClO—HCl—H₂O₂.

According to one embodiment, a first step c) is carried out with nitric acid, followed by a step d), then a second step c) is carried out with aqua regia, an acidic thiourea solution or a mixture of NaClO—HCl—H₂O₂.

### Step d)

Step d) of the method according to the invention is the step of separating the at least one acidic solution comprising at least a portion of the at least one metal and the rest of the LED obtained in step c).

Advantageously, the separation of the at least one acidic solution comprising at least part of the at least one metal and the rest of the LED obtained in step c), during step d), is carried out by filtration.

According to one embodiment, steps c) and d) are repeated several times, preferably according to step c) and then step d) then step c) and then step d) etc. Advantageously, the sequence of steps c) and d) is repeated with at least one acidic solution different from that used during the first sequence of steps c) and d).

Of course, when steps c) and d) are repeated, it is the rest of the LED obtained at the n^{th} step d) and not in step b) which is treated with (n+1)^{th} step c).

One of the advantages of the method according to the invention is that it allows a greater mass recovery of at least one metal of the LED than the methods of the prior art.

### Step e)

Step e) is an optional step of the method according to the invention for separating the at least one acidic solution and at least one portion of the at least one metal. This step aims to recover the at least one leached metal during step c), in particular with a view to recycling it.

According to one embodiment, the method according to the invention further comprises the recovery of at least part of the at least one precious metal by a step e) of separation of the at least one acidic solution and of at least part of the at least one metal, for example by filtration and/or electrodeposit and/or by a hydrometallurgical and/or precipitation method, in particular in the form of a salt.

The precipitation, in particular in the form of a salt, can be carried out at any suitable temperature, for example at room temperature or at high temperature, in particular around 70° C.

According to one embodiment, when the acidic solution separated from the rest of the LED during step d) comprises several metals, these metals can be precipitated selectively one after the other. Preferably, certain metals are first decanted and/or filtered, then the remaining metals are selectively precipitated one after the other. The filtration can in particular be carried out by filtration on a sieve, in particular on Teflon sieves.

For example, if the acidic solution separated from the rest of the LED during step d) comprises silver, copper and iron, these three metals can be selectively precipitated one after the other. Advantageously, they can be precipitated selectively one after the other using suitable precipitants, for example:
a NaCl solution for precipitating silver, and/or
an iron powder for precipitating copper, and/or
a NaOH solution for precipitating iron.

More advantageously, if the acidic solution separated from the rest of the LED during step d) comprises silver, copper and iron, these three metals can be precipitated selectively one after the other in the following order: silver then copper and then iron.

According to another example, if the acidic solution separated from the rest of the LED during step d) comprises silver, copper and tin, these three metals can be selectively precipitated one after the other. Advantageously, they can be precipitated selectively one after the other by using:
a NaCl solution for precipitating silver, and/or
a tin powder for precipitating copper, and/or
an iron powder for precipitating tin.

More advantageously, if the acidic solution separated from the rest of the LED during step d) comprises silver, copper and tin, these three metals can be precipitated selectively one after the other in the following order: silver then copper and then tin.

According to another example, if the acidic solution separated from the rest of the LED during step d) comprises silver, copper and iron, these three metals can be selectively precipitated one after the other. Advantageously, they can be precipitated selectively one after the other by using:
a NaCl solution for precipitating silver, and/or
a tin powder for precipitating copper, and/or
a NaOH solution for precipitating iron.

More advantageously, if the acidic solution separated from the rest of the LED during step d) comprises silver, copper and iron, these three metals can be precipitated selectively one after the other in the following order: silver then copper and then iron.

According to another embodiment, when the acid solution separated from the rest of the LED during step d) comprises several metals, these metals can be recovered selectively by electrodeposition, for example using a potentiostat.

According to one embodiment, when the acid solution separated from the rest of the LED during step d) comprises gold, it can be precipitated with NaBH₄. Advantageously, the precipitated gold can then be fused with borax in a furnace at 1000° C. to obtain metallic gold.

According to one embodiment, steps c) and d) and e) are repeated several times, preferably according to step c) and then step d) then step e) then step c) then step d) and then step e) etc. Advantageously, the sequence of steps c), d) and e) is repeated with at least one acidic solution different from that used during the first sequence of steps c), d) and e).

Advantageously, the method according to the invention can make it possible to recover the phosphor and metals from at least one electrode and from at least one connector of at least one LED.

### Semi-Conductor

According to one embodiment, the method according to the invention comprises the following steps:
a) at least partial depolymerization of the at least one layer comprising polydimethylsiloxane using a solution comprising at least one solvent and at least one fluorine salt;
b) Separation of the at least one phosphor and the rest of the LED obtained in step a);
b′) Separation of the at least one semi-conductor from the rest of the LED obtained in step b);
c′1) bringing at least one solution, preferably an acidic solution, into contact with the rest of the LED obtained in step b′);
c′2) Grinding and roasting of the at least one semi-conductor obtained in step b′) with Na₂CO₃ at 900° C. for 3 hours and then bringing at least one solution, preferably an acidic solution, with the at least one ground and roasted semi-conductor;
d′1) Separation of the at least one acidic solution of step c′1) comprising at least part of the at least one metal and the rest of the LED obtained in step c′1);
d′2) Separation of the at least one acidic solution of step c′2) comprising at least part of the at least one metal and of the rest of the at least one ground and roasted semi-conductor obtained in step c′2).

This embodiment of the method according to the invention makes it possible to recover the metals of at least one semi-conductor in addition to recovering the phosphor and metals from at least one electrode and from at least one connector.

The optional characteristics of steps a), b), c) and d), described above, apply respectively to steps a), b), c′1) and d′1) of this embodiment.

Advantageously, the solution used in step c′2) is a solution of hydrochloric acid 2.0 M. More advantageously, this hydrochloric acid solution 2.0 M allows the leaching of gallium and/or indium present in the at least one ground and roasted semi-conductor. Hydrochloric acid is preferably used in a liquid-solid mass ratio of 30 ml/g of the at least one ground and roasted semi-conductor. In particular, the step of leaching gallium and/or indium present in the at least one ground and roasted semiconductor lasts less than 1 hour, more particularly about 30 minutes.

Preferably, step d′2) is followed by a step e′) of separating the at least one acidic solution of step c′2) and at least part of the at least one metal, for example by precipitation and/or filtration and/or electrodeposit and/or hydrometallurgical process. Preferably, this step e′) allows the recovery of gallium and/or indium present in the at least one semi-conductor.

### LED Origin

According to one embodiment, the at least one LED used in the method according to the invention is of the chip-on-board (COB) type, of the filament type or of the surface-mounted device (SMD) type.

According to one embodiment, the at least one LED used in the method according to the invention originates from at least one device selected from the group consisting of bulbs, tubes, modules and luminaires.

According to one embodiment, the at least one LED comes from waste of electrical and electronic equipment (WEEE) or electrical and electronic products at the end of life (EOL).

According to one embodiment, the at least one LED comes from a screen, for example a television screen.

According to one embodiment, the at least one LED comes from an LED strip, preferably an LED strip present in a screen, more preferably an LED strip present in a television screen.

According to one embodiment, the at least one LED is covered by a layer comprising polyester, poly (ethylene terephthalate), polyurethane and/or polycarbonate, or present in a layer comprising polyester, poly (ethylene terephthalate), polyurethane and/or polycarbonate. Preferably, in this case, the method according to the invention comprises, before step a), a step 0) of degrading at least part of the polyester layer using a solution comprising a solvent and a fluorine salt. Preferably, the solution comprising a solvent and a fluorine salt used in step 0) is identical to that used in step a). Advantageously, steps 0) and a) are successive. Alternatively, steps 0) and a) are concomitant.

According to one embodiment, the at least one LED is covered by a polyester layer or present in a polyester layer, as is the case in the flexible strips of LEDs, in particular in the LED tubes Preferably, in this case, the method according to the invention comprises, before step a), a step 0) of degrading at least part of the polyester layer using a solution comprising a solvent and a fluorine salt. Preferably, the solution comprising a solvent and a fluorine salt used in step 0) is identical to that used in step a). Advantageously, steps 0) and a) are successive. Alternatively, steps 0) and a) are concomitant.

In this latter embodiment, the solution comprising a solvent and a fluorine salt used in step a) of the method according to the invention is advantageously a solution comprising TBAF and tetrahydrofuran. Indeed, it has been discovered, surprisingly, that such a solution makes it possible to simultaneously degrade the at least one layer comprising polydimethylsiloxane of the LED and the polyester layer.

### LED Recycling Process

In one embodiment, the method for extracting and separating at least one component of an LED according to the invention is implemented within a more global process for recycling a LED or a system comprising at least one LED.

### LED

The present invention also relates to an LED comprising at least one layer comprising polydimethylsiloxane, wherein the at least one layer comprising polydimethylsiloxane is depolymerized at least partially following the action of a solution comprising at least one solvent and at least one fluorine salt.

Preferably, said solution has the same characteristics as those described for the solution comprising a solvent and a fluorine salt used in step a) of the method according to the invention.

More preferably, said solution comprises tetrabutylammonium fluoride in a mixture of solvents comprising methyltetrahydrofuran and acetone or methyltetrahydrofuran and acetonitrile.

### EXAMPLES

The present invention will be better understood on reading the following examples which illustrate the invention in a non-limiting manner.

### Example 1: Study of the Efficacy of Various Solutions Comprising a Solvent and a Fluorine Salt to Depolymerize Polydimethylsiloxane

### Materials and Methods

PDMS samples are brought into contact with various solvents containing or not containing TBAF in order to evaluate the depolymerization capacity. PDMS is brought into contact with the solvent under the following conditions: 1 mL of solvent for 74 mg of PDMS.

### Results

The results of the depolymerization tests of PDMS are presented in the following table:

TABLE 1
Depolymerization of PDMS

| | TBAF | Solubility of | Depolymerization | Phosphor | | |
|---|---|---|---|---|---|---|
| Solvent | (mol/L) | TBAF/solvent | of PDMS | release | Time | |
| THF | 1 | + | + | + | <20 | min |
| THF | 0.1 | + | + | + | <20 | min |
| DCM | 1 | + | + | + | 30 | min |
| MeCN | 1 | + | + | + | 30 | min |
| DCM | 0 | − | − | − | NA | |
| DCM/Cyclohexane | 0 | − | − | − | NA | |
| 37/63 (in volume) | | | | | | |
| DCM/Cyclohexane | 0.33 | Phase | + | + | <25 | min |

| | | | | | |
|---|---|---|---|---|---|
| 37/63 (in volume) | | separation | | | |
| Toluene | 0 | − | − | − | NA |

The time indicated in Table 1 (straight column) corresponds to the time required to obtain sufficient depolymerization of the PDMS to allow the extraction of the phosphor from the LED. The indication NA specifies that the action of the solvent is not sufficient to depolymerize the PDMS sufficiently to allow the extraction of the phosphor from the LED.

The results show that PDMS is depolymerized in a solution of TBAF solubilized in tetrahydrofuran (THF), dichloromethane (CH₂Cl₂), trichloromethane (CHCl₃), acetonitrile (CH₃CN) or methyltetrahydrofuran (CH₃—THF).

### Example 2: Study of the Effect of the Concentration of TBAF in THF on the Depolymerization of PDMS

### Material and Methods

The depolymerization of PDMS in the TBAF/THF, at ambient temperature, was carried out at different concentrations of TBAF to study the kinetics.

### Results

The results are presented in the following table:

TABLE 2

| Concentration | | | | mmol of | | |
|---|---|---|---|---|---|---|
| of | Volume of | mmol of | Mass of | monomer of | | |
| TBAF (mol/L) | THF (mL) | TBAF | PDMS (mg) | PDMS | Depolymerization | |
| 1 | 1 | 1 | 74 | 1 | <20 | min |
| 0.8 | 1 | 0.8 | 74 | 1 | <20 | min |
| 0.6 | 1 | 0.6 | 74 | 1 | <20 | min |
| 0.4 | 1 | 0.4 | 74 | 1 | <20 | min |
| 0.2 | 1 | 0.2 | 74 | 1 | <30 | min |
| 0.1 | 1 | 0.1 | 74 | 1 | <1 | h |
| 0.05 | 1 | 0.05 | 74 | 1 | <2 | h |
| 0.04 | 1 | 0.04 | 74 | 1 | <2 | h |
| 0.03 | 1 | 0.03 | 74 | 1 | 3-4 | h |
| 0.02 | 1 | 0.02 | 74 | 1 | <24 | h |
| 0.01 | 1 | 0.01 | 74 | 1 | <30 | h |
| 0.005 | 1 | 0.005 | 74 | 1 | <5 | jours |

The effect of the TBAF concentration showed that the TBAF in THF is capable of depolymerizing the PDMS polymer at a molar ratio (monomer: TBAF, 1:0.005) in five days.

### Example 3: Study of the Effect of the Concentration of TBAF in CH₃—THF on the Depolymerization of PDMS

### Material and Methods

The depolymerization of PDMS in TBAF/CH₃—THF, at ambient temperature, was carried out at different concentrations of TBAF to study the kinetics. The solvent used is a binary solvent containing a few drops (less than 0.5 mL) of acetone in each CH₃—THF sample.

### Results

The results are presented in the following table:

TABLE 3

| | Volume | | Mass | | | |
|---|---|---|---|---|---|---|
| Concentration | of | mmol | of | mmol | | |
| ofTBAF | solvent | of | PDMS | of | | |
| (mol/L) | (mL) | TBAF | (mg) | PDMS | Depolymerization | |
| 0.1 | 1 | 0.1 | 74 | 1 | 1 | h |
| 0.05 | 1 | 0.05 | 74 | 1 | <2 | h |
| 0.04 | 1 | 0.04 | 74 | 1 | <3 | h |
| 0.03 | 1 | 0.03 | 74 | 1 | <3 | h |
| 0.02 | 1 | 0.02 | 74 | 1 | <24 | h |
| 0.01 | 1 | 0.01 | 74 | 1 | <48 | h |

The effect of the TBAF concentration showed that the TBAF in CH₃—THF is capable of depolymerizing the PDMS polymer at a molar ratio (monomer: TBAF, 1:0.01) within 48 hours.

### Example 4: Implementation of a Method for Recycling a LED According to the Invention

### Material and Methods

### PDMS Depolymerization

4000 commercial LEDs (SMD LED (2835), 6V 2W, of LEXTAR® brand) are placed in a 500 mL round-bottomed flask in which 250 mL of TBAF/CH₃—THF solution to 0.05 M are poured. The reaction mixture at room temperature is left overnight to give to TBAF the time required to dissolve PDMS. The mixture is filtered on a sieve to separate the LED from the phosphor. The LEDs are then washed with acetone to remove the entire phosphor residue. The solvents are collected and then the phosphor is left to stand. The solvents are removed by decantation, then the phosphor is washed twice with acetone and dried in the open air.

### LED Leaching

The LEDs are placed in a round-bottomed flask of 500 mL and then 250 mL of 4 M nitric acid are added and the mixture is brought to reflux at 60° C. The gas is released during the progress of the reaction. The blue solution is removed and replaced with 250 ml of 4 M nitric acid. The procedure is repeated until the disappearance of the metal bodies of the LEDs. At the end, it remains only the housings, semi-conductors and gold.

The metal bodies may also be leached using a HCl/H₂O₂ mixture.

### Silver Precipitation

To the blue solution collected, containing (Ag⁺, Cu²⁺ and Fe²⁺), 50 mL of a saturated NaCl solution are added and the assembly is stirred for 10 minutes to precipitate silver in the form of AgCl, which is then filtered on a Buchner. The white powder is washed with acetone and then dried to obtain pure AgCl. The mass of pure AgCl obtained is 0.32 g.

### Copper Precipitation

61g of iron powder are added to the blue solution, then the mixture is stirred for 30 minutes to precipitate copper. The iron powder is added progressively to precipitate copper. The solution becomes green at this stage. The copper powder is filtered, washed with water and then with acetone and dried. The mass of copper powder obtained is 62 g, which represents 89% of the copper which was present in the LEDs.

### Iron Precipitation

The solution obtained at this stage contains Na⁺ and Fe²⁺ (probably a few traces of Cu²⁺). To precipitate iron, a 2M NaOH solution is added in a sufficient quantity so that all Fe²⁺ precipitates, then the mixture is stirred for 30 minutes to obtain a Fe(OH)₂ powder. The NaOH solution is added small to small until the complete precipitation of Fe(OH)₂. The blue precipitate is filtered, washed with water and then with acetone, then dried. The mass of Fe(OH)₂ powder obtained is 95 g.

### Gold Recovery

In the original reaction flask, gold wires, casings and semiconductors still remain. To the flask, 25 ml of a freshly prepared solution of aqua regia (mixture of hydrochloric acid and nitric acid, the ratio of which volume HCl: HNO₃ is 4:1, v/v) are added. Then, the solution is heated for 1 hour at 70° C. Then, a new quantity (25 ml) of aqua regia is added and the solution is heated again for one hour. Finally, the solution is removed with a syringe, concentrated on a heating plate and then 1 g of NaBH₄ is added to the solution to precipitate the gold in the form of brown precipitate (a solution of Fe²⁺ (FeSO₄ or FeCl₂) can also be used to precipitate gold). The precipitate is filtered, washed with water and then with acetone. Finally, the gold brown powder obtained is placed in a crucible to which 0.5 g of borax is added and then melted in a furnace at 1000° C. for 15 min to obtain gold metal. It should be noted that gold can also be leached with an acidic thiourea solution, with a mixture of (acetic acid-HCl—CaCl₂—H₂O₂) or with a mixture of NaClO—HCl—H₂O₂. the mass of gold powder obtained is 153 mg.

### Results

The method for recycling LEDs (4000 chips) allows the extraction and separation of 0.32 g of AgCl, 62 g of copper powder, 95 g of Fe(OH)₂ powder and 153 mg of gold powder. The extraction and separation method according to the invention therefore allows the efficient recovery of the phosphor and metals present in the LEDs with a high yield. By way of example, 89% of the copper present in the LEDs was recovered.

1-10. (canceled)

11. A method for extracting and separating at least one component of an LED, the LED comprising at least one metal, at least one phosphor and at least one layer comprising polydimethylsiloxane, said method comprising the following steps:
a) at least partial depolymerization of at least one layer comprising polydimethylsiloxane using a solution comprising a solvent and a fluoride salt;
b) separation of the at least one phosphor and the rest of the LED obtained in step a);
c) contacting at least one acidic solution with the rest of the LED obtained in step b); and
d) separation of the at least one acidic solution comprising at least part of the at least one metal and the rest of the LED obtained in step c).

12. The method according to claim 11, wherein the solvent of the solution used in step a) is selected from the group consisting of tetrahydrofuran, methyltetrahydrofuran, dichloromethane, trichloromethane, acetonitrile, dimethylformamide, N-methyl-2-pyrrolidone, binary solvents, and mixtures thereof, the binary solvents being selected from the group consisting of methyltetrahydrofuran and acetone, methyltetrahydrofuran and acetonitrile, methyltetrahydrofuran and dimethylformamide, and methyltetrahydrofuran and trichloromethane.

13. The method according to claim 11, wherein the fluoride salt of the solution used in step a) is a quaternary ammonium fluoride selected from the group consisting of tetrabutylammonium fluoride (TBAF), tetramethylammonium fluoride (TMAF), tetraethylammonium fluoride (TEAF) and tetra-n-octylammonium fluoride (TOAF).

14. The method according to claim 11, wherein the at least one acidic solution used in step c) is selected from the group consisting of nitric acid, aqua regia, an acidic thiourea solution, sulfuric acid, a mixture of NaClO—HCl—H₂O₂, a mixture of (acetic acid-HCl—CaCl₂—H₂O₂), a mixture HCl—H₂O₂ and mixtures thereof.

15. The method according to claim 11, further comprising recovering at least a part of the at least one metal by a step e) of separating the at least one acidic solution from at least a part of the at least one metal, for example by precipitation and/or filtration.

16. The method according to claim 11, wherein the sequence of process steps c) and d) is repeated with at least one solution different from that used in the first sequence of steps c) and d).

17. The method according to claim 11, wherein the at least one metal of the LED is selected from the group consisting of gold, silver, copper, aluminum, tin, iron and combinations thereof.

18. The method according to claim 11, wherein the at least one LED is coated by a polyester layer or is present in a polyester layer, and wherein said method comprises, prior to step a), a step 0) of degrading at least a part of the polyester layer using a solution comprising a solvent and a fluorine salt.

19. The method according to claim 18, wherein steps 0) and a) are successive or concomitant.

20. An LED comprising at least one layer comprising polydimethylsiloxane, wherein the at least one layer comprising polydimethylsiloxane is depolymerized by the action of a solution comprising a solvent and a fluorine salt.
